(19) United States
(12) Patent Application Publication
(10) Pub. No.: US 2013/0009328 A1
(43) Pub. Date: Jan. 10, 2013

(54) ALIGNMENT MARK, SEMICONDUCTOR HAVING THE ALIGNMENT MARK, AND FABRICATING METHOD OF THE ALIGNMENT MARK

(75) Inventors: Tai-Ho Wang, Hsinchu City (TW); Jia-Luen Peng, Taoyuan County (TW); Hung-Sheng Yu, Hsinchu County (TW)

(73) Assignee: ORISE TECHNOLOGY CO., LTD., Hsinchu City (TW)

(21) Appl. No.: 13/541,636

(22) Filed: Jul. 3, 2012

(30) Foreign Application Priority Data
Jul. 8, 2011 (TW) 100124260

(51) Int. Cl. H01L 23/544; H01L 21/3205

(52) U.S. Cl. 257/797; 438/584; 257/E23.179; 257/E21.295

(57) ABSTRACT

An alignment mark with a sheet or a layer of copper, which is compatible with a copper process, is provided herein. In one embodiment, a whole sheet of copper (Cu) is used as a background of the alignment mark, by which the color of the background of the alignment mark is stable and reliable. By such arrangement, the contrast between colors of a main pattern and the background of the alignment mark can be significantly improved, without considering a problem the homogeneity of manufacturing process. If the alignment mark is applied for manufacturing of a display, a recognition successful rate of alignment to attach an integrated circuit (IC) to a panel of the display is increased.

### CROSS-REFERENCE TO RELATED APPLICATION

This application claims the priority benefit of Taiwan application serial no. 100124260, filed on Jul. 8, 2011. The entirety of the above-mentioned patent application is hereby incorporated by reference herein and made a part of this specification.

### BACKGROUND OF THE INVENTION

1. Field of the Invention

The invention relates to an alignment mark structure and a fabricating method thereof. Particularly, the invention relates to an alignment mark structure of a semiconductor device, and a fabricating method thereof.

2. Description of Related Art

When a semiconductor device is fabricated or a display module is fabricated and assembled, various devices are generally configured within a tolerable error range. When an integrated circuit (IC) is adhered or fixed to a glass panel of a display module, an alignment mark is used to locate the IC device to a correct position.

FIG. 1A is a top view of a conventional alignment mark structure, and FIG. 1B is a schematic diagram of a relative position of the alignment mark structure on an IC device 140. The alignment mark structure may include two alignment marks T1 and T2 located at two sides of the IC device 140. The alignment mark 100 includes a mark main pattern 130 and a peripheral area 120. The mark main pattern 130 has a cross shape, which can be used as positioning coordinate axes including an X-axis and a Y-axis. As shown in FIG. 1B, after the IC device 140 is fabricated, it has the alignment marks T1 and T2 at two sides. The IC device 140 is disposed on a surface of the glass panel of the display module, and is interconnected with the glass panel or is electrically connected to a circuit of the surface. In order to accurately dispose the IC device 140 on the glass panel at a correct position, the alignment marks T1 and T2 at two sides of the IC device 140 serve as references for location alignment.

An optical manner is generally used for alignment, by which an incident light irradiates the IC device 140 to read positions of the alignment marks T1 and T2 and align the mark main pattern 130, so as to serve as references for position adjustment and alignment. Referring to FIG. 1C, FIG. 1C is a schematic diagram of a bonding device used for bonding the IC device 140 with a glass panel. The bonding device includes a bonding base 150. A glass panel 160 of the display module is disposed on the surface of the bonding base 150, and a bonding head 152 is located above the bonding base 150, which can be moved by a machine or manpower.

When the IC device 140 is about to be disposed on the surface of the glass panel 160, it can be directly adhered thereon, and an adhering method thereof is to use an anisotropic conductive film (ACF) 156 and a thermo couple 154 for electric connection. In order to dispose the IC device 140 on the glass panel 160 at a correct position, an alignment procedure is generally performed, and the alignment is implemented through the alignment marks on the IC device 140. When the incident light irradiates the IC device 140, the mark main pattern 130 of the alignment mark can effectively reflect the incident light, and a light reflection effect of the peripheral area 120 is inferior to that of the surface of the mark main pattern 130. Therefore, according to a reflection contrast of the two regions for the incident light, a position and a shape of the mark main pattern 130 can be effectively obtained, so as to facilitate the position alignment and adjustment.

Due to a homogeneity problem of a manufacturing process, the background area (i.e. the peripheral area) of the alignment mark has a problem of variations of color difference, which may influence a recognition success rate of alignment. FIG. 2A and FIG. 2B are schematic diagrams illustrating the color difference of the background areas of the alignment marks. As shown in FIG. 2A and FIG. 2B, when the alignment mark is fabricated, since homogeneity control is difficult in the manufacturing process, thickness of local area materials cannot be exactly the same, so that the background areas of the alignment marks of different IC devices may have different colors. Then, when alignment bonding is performed in the panel factory, a problem that the alignment marks cannot be positioned is occurred.

To resolve such problem, U.S. Pat. No. 7,821,638 provides an alignment mark. In such patent, as shown in FIG. 3A, an alignment mark 300 includes a first pattern 320 and a second pattern 302 surrounding the first pattern 320. The second pattern 302 is composed of a plurality of fine patterns 330. The first pattern 320 is disposed on a higher plane, and the first pattern 320 perpendicular to the incident light can reflect the incident light for aligning the mark main pattern, which can serve as a reference for obtaining vertex position coordinates through optical measurement during wafer fabrication. The fine patterns 330 are sequentially disposed on a substrate along an x-axis and a y-axis of a Cartesian coordinate system according to a predetermined pitch, wherein the fine patterns 330 can scatter the perpendicular incident light to all directions.

FIG. 3B is a schematic diagram of another alignment mark provided by the U.S. Pat. No. 7,821,638. The alignment mark 300A is a reverse version of the above alignment mark 300. FIG. 3C is a structural diagram of the alignment mark provided by the U.S. Pat. No. 7,821,638, i.e. a cross-sectional view of the alignment mark.

The alignment mark 300 includes a plurality of alignment layers 304, 306 and 308. The first alignment layer 304, the second alignment layer 306 and the third alignment layer 308 are sequentially stacked on a substrate 302 along a direction perpendicular to the materials, wherein when a parallel light is incident to the first pattern 320, most of the light is reflected, as that shown by a reflected light L1. Comparatively, since when the incident light is incident to the pitch between the fine patterns 330, irregular reflected light L2 is generated, and when the alignment mark is inspected according to the reflected light, contrast between the reflected light L1 and the irregular reflected light L2 is observed, which facilitates recognizing the alignment mark according to the difference of the contrast. However, since a direction of the reflected light L2 is irregular, a problem of too great difference of the background colors is encountered. Moreover, the cost is increased due to a relatively complicated manufacturing process.

When the aforementioned techniques are applied to manufacture display devices, a chip-on-glass (COG) process has to be performed to remove an anti-reflection layer of a main pattern metal layer on the alignment mark, by which not only an additional process time and the fabrication cost are increased, since such process may cause a difference of the background color in different areas when homogeneity of a passivation layer is poor, the recognition success rate of alignment is influenced.

### SUMMARY OF THE INVENTION

The invention is directed to an alignment mark, adapted to a copper process in integrated circuit (IC) fabrication, which enhances a contrast between colors of a main pattern and a background pattern of the alignment mark to facilitate determining alignment for attaching the IC to a liquid crystal panel. The alignment mark can effectively enhance a recognition successful rate of alignment to attach the IC of the LCD to the panel.

The invention provides an alignment mark including a background pattern, a first dielectric layer, a second dielectric layer and a mark main pattern. The background pattern is located in the first dielectric layer, where the background pattern is formed by a copper layer. The second dielectric layer is located on the first dielectric layer, and covers a surface of the background pattern. The mark main pattern is disposed on the second dielectric layer and located above a coverage area of the background pattern, where the mark main pattern is made of aluminium or aluminium copper alloy, and is used for forming a contrast color with that of the background pattern to facilitate determining alignment for attaching an integrated circuit (IC) to a liquid crystal panel.

In an embodiment of the invention, the alignment mark further includes a third dielectric layer and a fourth dielectric layer. The third dielectric layer covers the mark main pattern, and the fourth dielectric layer covers the third dielectric layer, where the third dielectric layer and the fourth dielectric layer serve as a passivation layer of the IC and the alignment mark. In an embodiment, the third dielectric layer is a stress relief oxide (SRO) layer, and the fourth dielectric layer includes a silicon nitride (Si₃N₄) layer.

In an embodiment of the invention, the mark main pattern has a cross shape, an I-shape or a T-shape.

In an embodiment of the invention, the copper layer is a whole sheet of copper layer. In another embodiment, the copper layer is arranged in a square array formed by rectangles.

The invention provides an alignment mark including a mark main pattern, a first dielectric layer, a second dielectric layer and a background pattern. The mark main pattern is formed by a copper layer and is located on the first dielectric layer, where the copper layer is a whole sheet of copper layer or is arranged in a square array formed by rectangles. The second dielectric layer is located on the first dielectric layer, and covers the mark main pattern. The background pattern is disposed on the second dielectric layer, and is located above the mark main pattern, where the background pattern is made of aluminium or aluminium copper alloy, and is used for forming a contrast color with that of the mark main pattern to facilitate determining alignment for attaching an integrated circuit (IC) to a liquid crystal panel.

In an embodiment of the invention, the alignment mark further includes a third dielectric layer and a fourth dielectric layer. The third dielectric layer covers the mark main pattern, and the fourth dielectric layer covers the third dielectric layer, where the third dielectric layer and the fourth dielectric layer serve as a passivation layer of the IC and the alignment mark. In an embodiment, the third dielectric layer is a SRO layer, and the fourth dielectric layer includes a silicon nitride layer (Si₃N₄).

In an embodiment of the invention, the mark main pattern has a cross shape, an I-shape or a T-shape.

In an embodiment of the invention, the copper layer arranged in a square array formed by rectangles has one layer or different layers.

The invention provides a method for fabricating an alignment mark, adapted to a copper process in integrated circuit (IC) fabrication, and the method includes following steps. A substrate is provided to form an alignment mark structure. A copper layer and a first dielectric layer surrounding the copper layer are formed on the substrate, where the copper layer is a whole sheet of copper layer or is arranged in a square array formed by rectangles. A second dielectric layer is formed on the first dielectric layer and the copper layer. A mark main pattern is configured on the second dielectric layer, and is located above a coverage area of the copper layer, where the mark main pattern is made of aluminium or aluminium copper alloy, and forms a contrast with a color of the background pattern in the alignment mark structure to facilitate determining alignment for attaching an integrated circuit (IC) to a liquid crystal panel.

In an embodiment of the invention, the method further includes following steps. A third dielectric layer is formed to cover the mark main pattern. A fourth dielectric layer is formed to cover the third dielectric layer, where the third dielectric layer and the fourth dielectric layer serve as a passivation layer of the alignment mark. In an embodiment, the third dielectric layer is a SRO layer. In another embodiment, the fourth dielectric layer includes a silicon nitride layer (Si₃N₄).

In an embodiment of the invention, a groove area is dug in the first dielectric layer to implant a copper metal seed, and electroplating and chemical mechanical polishing processes are performed to form the copper layer.

In an embodiment of the invention, the mark main pattern has a cross shape, an I-shape or a T-shape.

In an embodiment of the invention, the copper layer arranged in a square array formed by rectangles has one layer or different layers.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view of a conventional alignment mark.

FIG. 1B is a schematic diagram of a relative position of alignment marks on a wafer.

FIG. 1C is a schematic diagram of a bonding device used for bonding the IC device with a glass panel.

FIG. 2A and FIG. 2B are schematic diagrams illustrating a situation that alignment marks generate error messages.

FIG. 3A and FIG. 3B are top views of conventional alignment mark structures.

FIG. 3C is a cross-sectional view of a conventional alignment mark structure.

FIG. 4 is a cross-sectional view of an alignment mark structure.

FIG. 5A is a top view of an alignment mark structure using a whole sheet of copper layer as a background pattern and using an aluminium layer as a mark main pattern according to an embodiment of the invention.

FIG. 5B is a light incident/reflection diagram and a cross-sectional view of an alignment mark structure using a whole sheet of copper layer as a background pattern and using an aluminium layer as a mark main pattern according to an embodiment of the invention.

FIG. 6A is a cross-sectional view of an alignment mark structure using a whole sheet of aluminium layer as a background pattern and using a copper layer as a mark main pattern according to another embodiment of the invention.

FIG. 6B is a light incident/reflection diagram and a cross-sectional view of an alignment mark structure using a whole sheet of aluminium layer as a background pattern and using a copper layer as a mark main pattern according to another embodiment of the invention.

FIG. 7 is a flowchart illustrating a method for fabricating an alignment mark using a whole sheet of copper layer as a background pattern according to an embodiment of the invention.

FIG. 8A is a top view of an alignment mark structure using a copper layer arranged in a square array as a background pattern and using an aluminium layer as a mark main pattern according to another embodiment of the invention.

FIG. 8B is a light incident/reflection schematic diagram and a cross-sectional view of an alignment mark structure using a copper layer arranged in a square array as a background pattern and using an aluminium layer as a mark main pattern according to an embodiment of the invention.

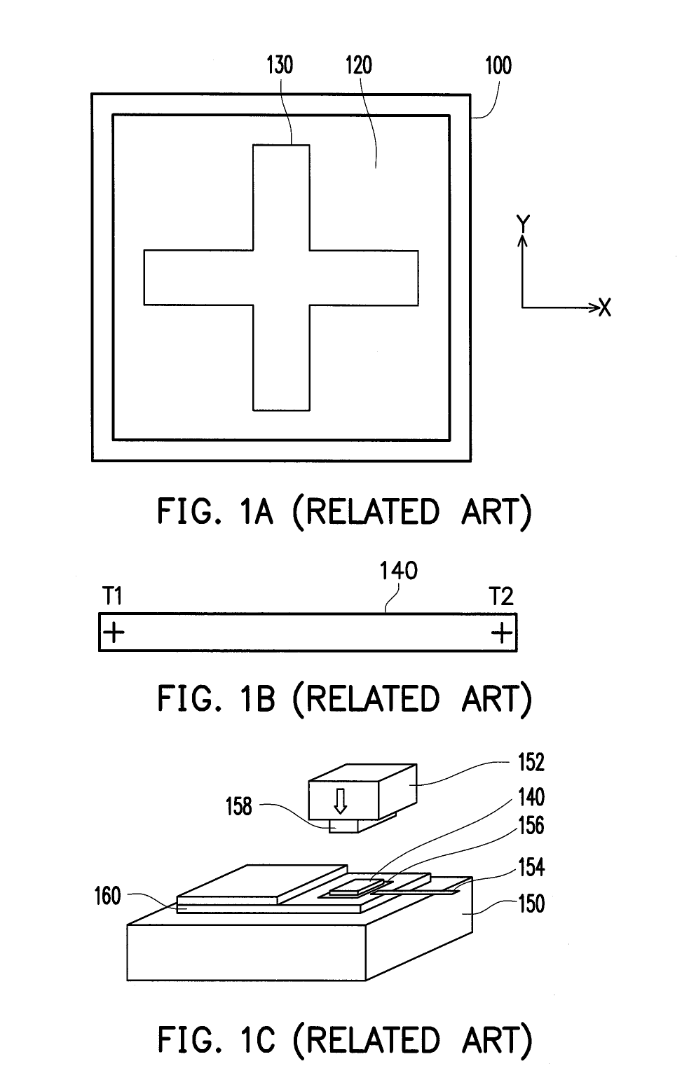

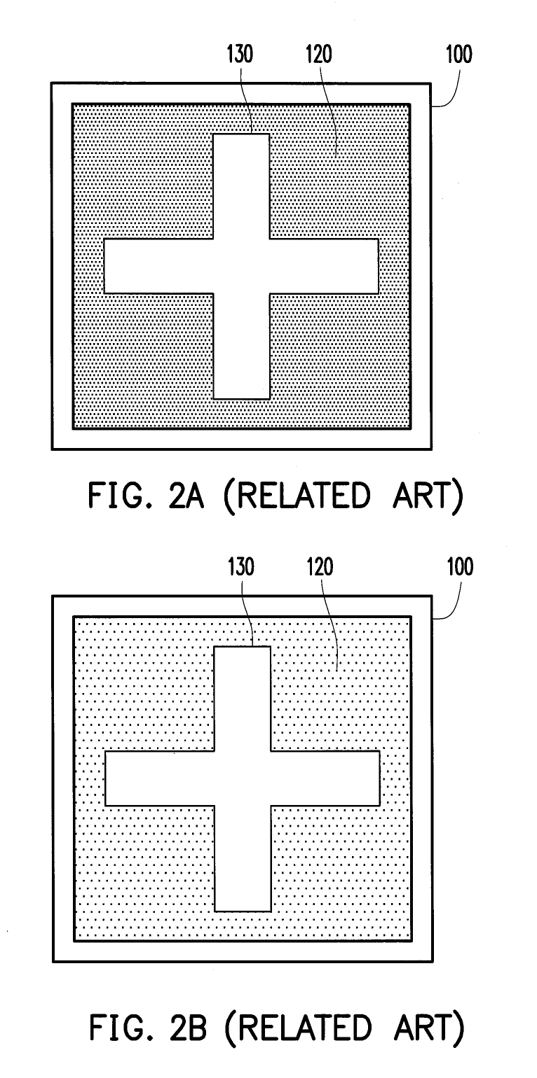

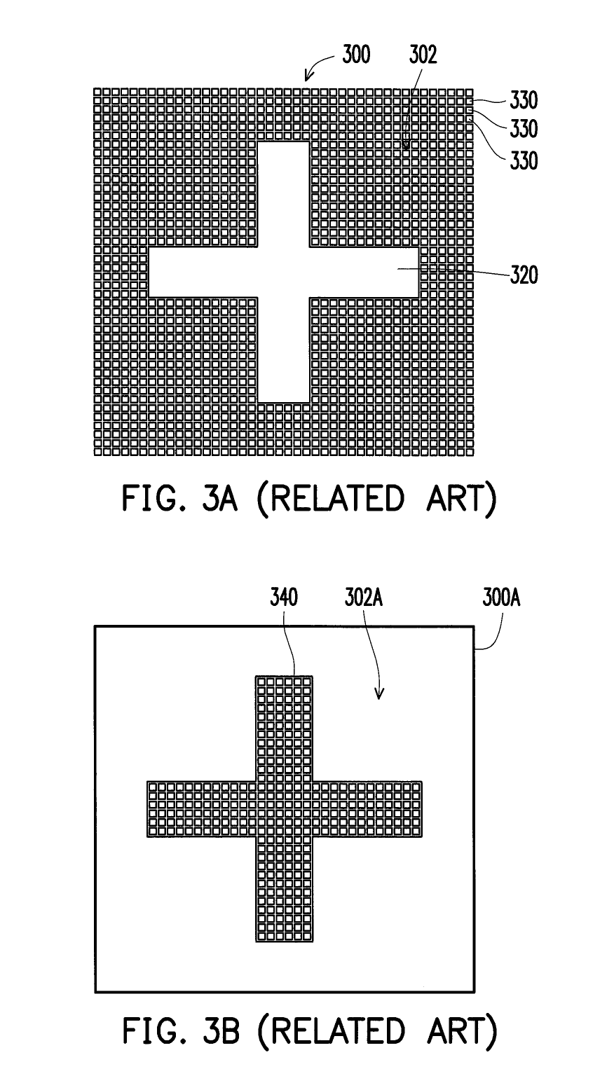

### DETAILED DESCRIPTION OF DISCLOSED EMBODIMENTS

The invention provides an alignment mark with a whole sheet of copper layer or a copper layer arranged in a square array, which is adapted to an existing copper process.

In an embodiment, if the whole sheet of copper layer or the copper layer arranged in a square array is applied to a background of the alignment mark, a color of the background may be fixed without considering a problem of homogeneity of the manufacturing process, and a contrast between the colors of the background and a mark main pattern is significantly improved. If the alignment mark is applied to manufacture a liquid crystal display (LCD), a recognition successful rate of alignment to attach an integrated circuit (IC) to a panel of the LCD is increased. In another embodiment, the whole sheet of copper layer or the copper layer arranged in a square array can also be applied to the mark main pattern of the alignment mark.

An embodiment of the invention provides an IC including an alignment mark structure including the whole sheet of copper layer or the copper layer arranged in a square array. In an embodiment, the whole sheet of copper layer or the copper layer arranged in a square array is used as a background pattern of the alignment mark, and in another embodiment, it is used as a main pattern of the alignment mark.

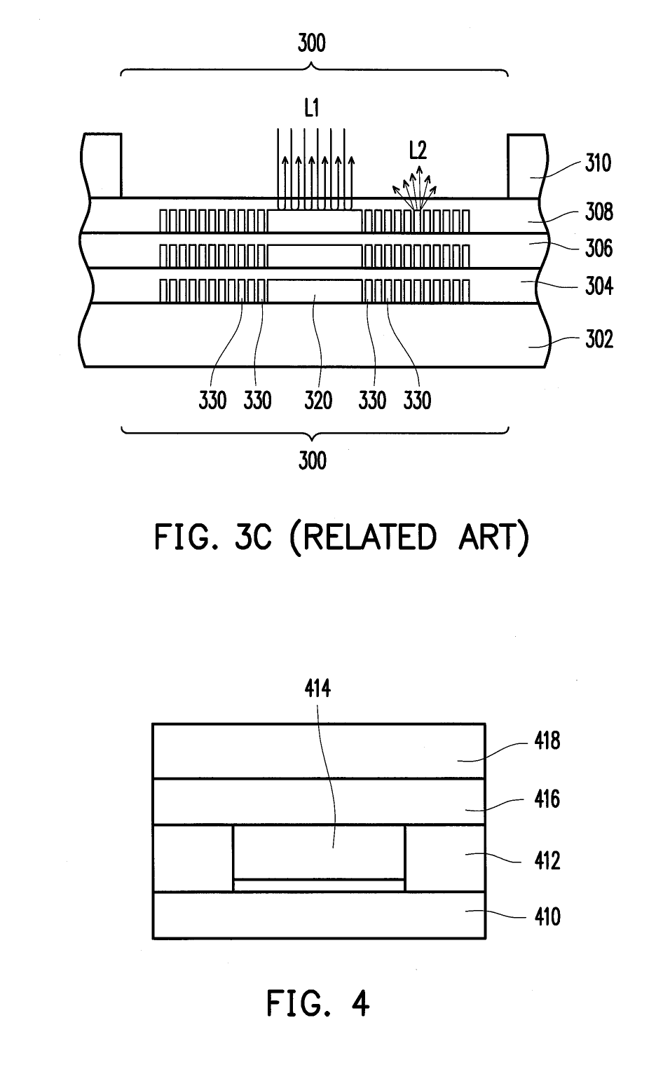

FIG. 4 is a cross-sectional view of an alignment mark structure on an IC.

Referring to FIG. 4, the alignment mark structure generally includes a base layer, for example, a dielectric layer 410, and a dielectric layer 412 and a mark main pattern 414 of the alignment mark are formed thereon. Moreover, a stress relief oxide (SRO) layer 416 and a silicon nitride (Si₃N₄) layer 418 are formed thereon.

To fabricate the alignment mark structure, a high density plasma process is used to etch a wafer, and then a chemical mechanical polishing (CMP) process is performed to polish metal oxide on the wafer. An aluminium copper (AlCu) layer is formed on the dielectric layer 410, and the mark main pattern 414 is fabricated in a method the same as a method of directly fabricating a logic circuit on the dielectric layer 410 in the LCD. The dielectric layer 412 is formed at periphery of the mark main pattern 414. An SRO layer 416 is formed on the mark main pattern 414 and the dielectric layer 412, and the silicon nitride (Si₃N₄) layer 418 is formed on the SRO layer 416. The SRO layer 416 and the silicon nitride (Si₃N₄) layer 418 serve as a passivation layer of the alignment mark.

In the above processes, since a thickness of the silicon nitride (Si₃N₄) layer 418 cannot be even during the manufacturing process, color dispersion phenomenon of different colors is produced under different thickness. According to a measurement result, from a film thickness of 380 angstrom (Å), 530 Å, 750 Å, 900 Å, 1130 Å, 1280 Å to 1500 Å, the presented color is varied from yellow brown, brown, dark purple to amaranth, reddish dark blue, light blue to metallic blue, and metallic color to pale yellow-green. Moreover, from a film thickness of 2330 Å, 2930 Å, 3530 Å, 3680 Å, 3900 Å, 4500 Å, 6000 Å, 8900 Å to 10600 Å, the present color is varied from blue, yellow, purple, blue, green, pink, orange, blue to purple. Detailed data is listed in a following table 1 of a thermal growth Si₃N₄ film color table.

TABLE 1
hot growth Si₃N₄ film color table
(vertical observation under fluorescent light)
Film thickness

| Å | μ | Color and note |
|---|---|---|
| 380 | 0.038 | Yellow brown |
| 530 | 0.053 | Brown |
| 750 | 0.075 | Dark purple to |
| | | amaranth |
| 900 | 0.09 | Reddish dark blue |
| 1130 | 0.113 | Light blue to |
| | | metallic blue |
| 1280 | 0.128 | Metallic color to |
| | | pale yellow-green |
| 1500 | 0.15 | Pale gold or light |
| | | metallic yellow |
| 1650 | 0.165 | Gold with light |
| | | yellow orange |
| 1880 | 0.188 | Orange to |
| | | watermelon |
| 2030 | 0.203 | Red purple |
| 2250 | 0.225 | Blue to purple blue |
| 2330 | 0.233 | Blue |
| 2400 | 0.240 | Blue to blue green |
| 2550 | 0.255 | Light green |
| 2630 | 0.263 | Green to yellow |
| | | green |
| 2700 | 0.270 | Yellow green |
| 2780 | 0.278 | Green yellow |
| 2930 | 0.293 | Yellow |
| 3070 | 0.307 | Light orange |
| 3150 | 0.315 | Amaranth |
| 3300 | 0.330 | Amaranth |
| 3450 | 0.345 | Red purple |
| 3530 | 0.353 | Purple |
| 3600 | 0.360 | Blue purple |
| 3680 | 0.368 | Blue |
| 3750 | 0.375 | Blue green |
| 3900 | 0.390 | Green (sketchily) |
| 4050 | 0.405 | Yellow green |
| 4200 | 0.42 | Light yellow |
| 4280 | 0.428 | Light orange |
| 4350 | 0.435 | Light orange to the |
| | | middle of yellow |
| | | and pink |
| 4500 | 0.45 | Pink |
| 4720 | 0.472 | Amaranth |
| 5100 | 0.510 | Middle of purple and |
| | | blue green; light |
| | | gray |
| 5400 | 0.54 | Blue green to green |
| 5780 | 0.578 | Light yellow |
| 6000 | 0.6 | Orange |
| 8200 | 0.82 | Orange red |
| 8500 | 0.85 | Dim red purple |
| 8600 | 0.86 | Purple |
| 8700 | 0.87 | Blue purple |
| 8900 | 0.89 | Blue |
| 9200 | 0.92 | Blue green |
| 9500 | 0.95 | Dim yellow green |
| 9700 | 0.97 | Yellow to light |
| | | yellow |
| 9900 | 0.99 | Orange |
| 10000 | 1.00 | Pink |
| 10200 | 1.02 | Amaranth |
| 10500 | 1.05 | Red purple |
| 10600 | 1.06 | Purple |

According to the above experiment data, it is known that the colors corresponding to different thickness are presented in cycle, and the presented color cannot be accurately controlled, i.e. different colors may cause different color contrast, which may lead to difficulty in measuring alignment through an optical manner. The above thickness variation of the Si₃N₄ film from a small range to a large range corresponds to many color shift situations, and the IC device may present a plurality of different colors, which may severely influence recognition and alignment of the IC device, and cause alignment failure.

Therefore, the invention provides a manufacturing process of an alignment mark structure adapted to an existing copper process, which can improve the color contrast of the alignment mark, and mitigate the color shift phenomenon in optical alignment generated when the passivation layer is inconsistent in the manufacturing process, and improve accuracy in measuring alignment through the optical manner.

In one of the embodiments, a whole sheet of copper layer can be used in the alignment mark structure to serve as either a mark main pattern or a background of the mark main pattern. In one of the embodiments, the whole sheet of copper layer can be used in the background of the alignment mark to fix a color of the background, so as to avoid a problem of homogeneity in the manufacturing process, and improve a contrast between the colors of the background and the mark main pattern. If the alignment mark is applied to manufacture a LCD, a recognition successful rate of alignment to attach the IC to a panel of the LCD is increased.

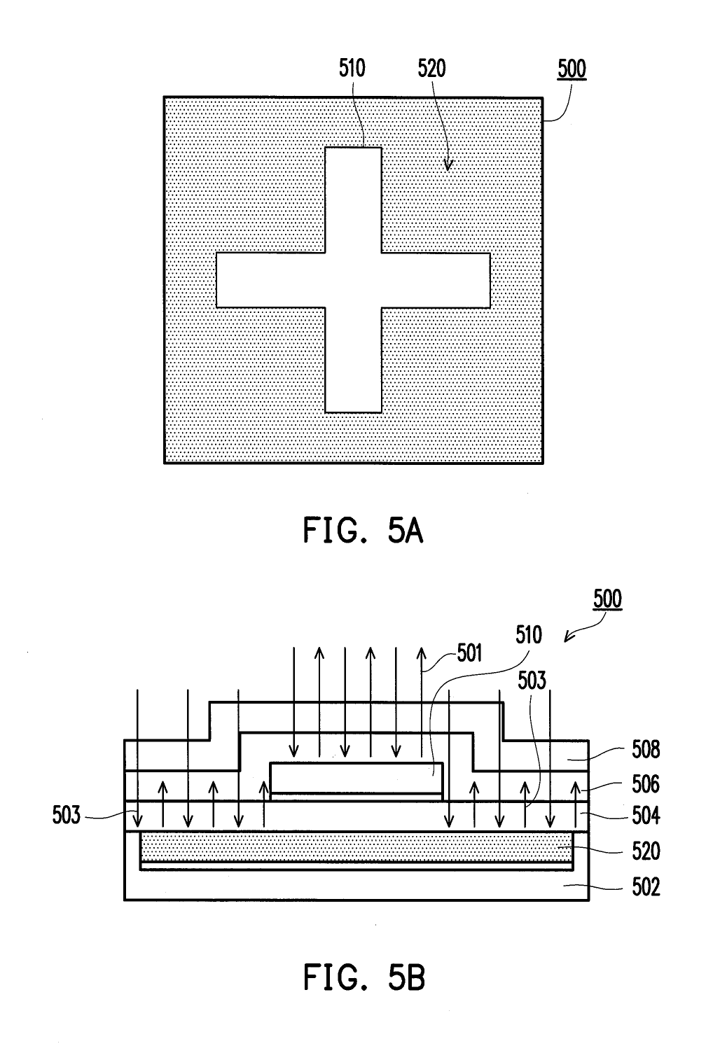

FIG. 5A is a top view of an alignment mark structure using the whole sheet of copper layer as the background pattern of the alignment mark according to one of embodiments of the invention. The alignment mark structure 500 of the present embodiment includes a mark main pattern 510 and a background pattern 520. In an embodiment, the mark main pattern 510 may have different pattern shapes according to a design requirement to facilitate the alignment procedure, for example, a cross shape, though the invention is not limited thereto. A material of the mark main pattern 510 is aluminium copper (AlCu) alloy, which generally presents a color of silver white. The background pattern 520 is formed by the whole sheet of copper layer. The whole sheet of copper layer presents a color of scarlet, which serves as the background of the present embodiment. According to the above descriptions, it is known that the mark main pattern 510 presenting the silver white color and the background pattern 520 (the whole sheet of copper layer) presenting the scarlet may have a high contrast color difference to highlight a shape of the main pattern, so as to improve the alignment accuracy.

FIG. 5B is a cross-sectional view of an alignment mark structure using the whole sheet of copper layer as the background pattern of the alignment mark according to an embodiment of the invention. The substrate includes a first dielectric layer 502, and the first dielectric layer 502 includes the background pattern 520. The background pattern 520 can be formed by the whole sheet of copper layer to serve as the background of the alignment mark. A method of forming the background pattern 520 formed by the whole sheet of copper layer can be collaborated with a copper process in semiconductor fabrication. In an embodiment, a groove area is dug in the first dielectric layer 502, and a copper metal seed is implanted therein, and then electroplating and chemical mechanical polishing (CMP) processes are performed to form the background pattern 520 of the whole sheet of copper layer.

Then, a second dielectric layer 504 is formed on the first dielectric layer 502 to cover or wrap the background pattern 520. Then, the mark main pattern 510 of the alignment mark structure is formed on the second dielectric layer 504, and a passivation layer is formed on the mark main pattern 510 to warp and protect the mark main pattern 510. For example, in an embodiment, a third dielectric layer 506 is formed on the second dielectric layer 504, where the third dielectric layer 506 can be a stress relief oxide (SRO) layer. The third dielectric layer 506 is covered by a silicon nitride (Si₃N₄) layer 508. The third dielectric layer 506 and the silicon nitride (Si₃N₄) layer 508 can serve as the passivation layer of the alignment mark.

In the present embodiment, the background pattern 520 of the alignment mark structure 500 applies the whole sheet of copper layer. In an embodiment, the background pattern 520 can be presented by smaller areas of copper of a same layer or different layers that are arranged in rectangles, so as to collaborate with the existing copper process. The material of the mark main pattern 510 is aluminium copper (AlCu) alloy. As described above, the aluminium copper (AlCu) alloy presents a color of silver white, and the whole sheet of copper layer or the copper layer arranged in a square array that serves as the background presents a color of scarlet, so that a high contrast color difference is presented to highlight a shape of the main pattern, so as to improve the alignment accuracy. For example, an incident light has a sufficient reflection effect at the mark main pattern 510, as that shown by a referential number 501, though if the incident light falls on the background pattern 520, a reflection effect thereof is inferior to the reflection effect of the mark main pattern 510, as that shown by a referential number 503.

In the present embodiment, the shape of the mark main pattern 510 may be different according to different design requirements, and in an embodiment, it may be a cross shape for defining coordinate axes including an X-axis and a Y-axis, and regions thereon that extend upwards, downwards, leftwards and rightwards can increase contrast information, though the invention is not limited to the cross shape, and any shape that can be used as the alignment mark is applicable for the present embodiment, for example, a T shape, an I shape or other shapes.

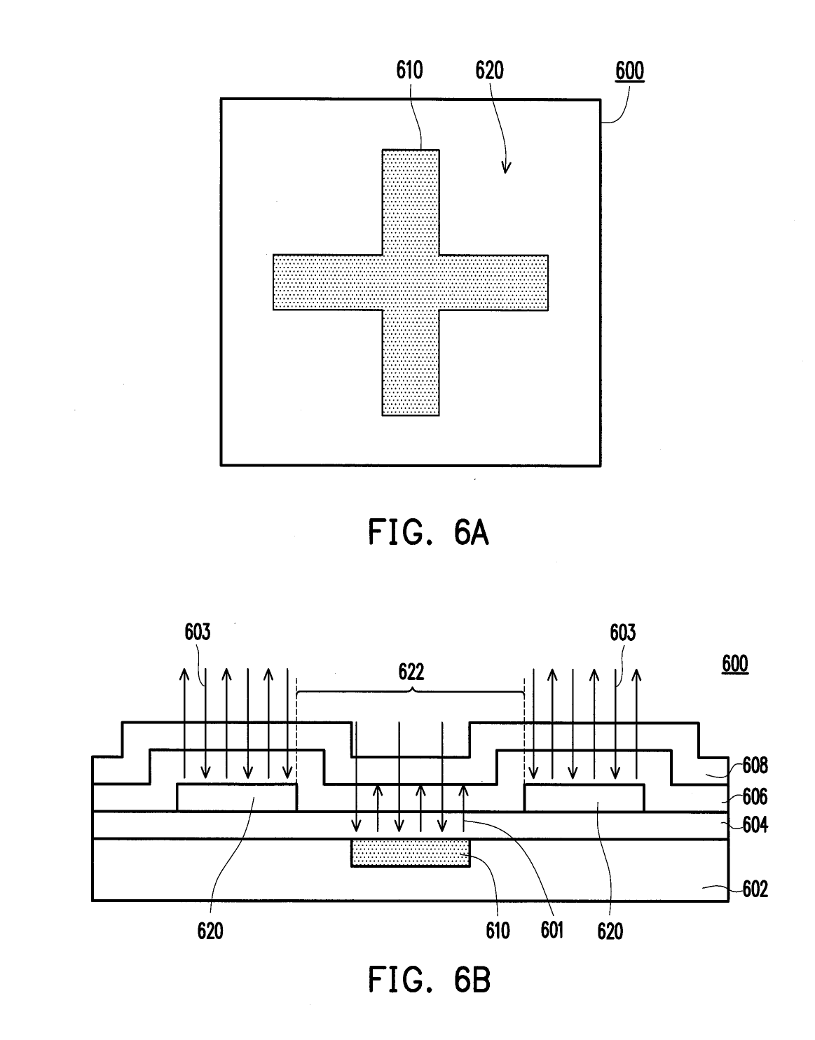

FIG. 6A is a cross-sectional view of an alignment mark structure using the copper layer as the mark main pattern according to another embodiment of the invention. The alignment mark structure 600 includes a mark main pattern 610 and a background area 620. In an embodiment, the mark main pattern 610 may have different shapes according to different design requirements to facilitate the alignment procedure, for example, a cross shape, though the invention is not limited thereto. A material of the mark main pattern 610 is the whole sheet of copper layer or the copper layer arranged in a square array, and the whole sheet of copper layer or the copper layer arranged in a square array presents a color of scarlet to serve as the mark main pattern of the present embodiment. The background area 620 is made of the aluminium copper (AlCu) alloy, which generally presents a color of silver white. According to the above descriptions, it is known that the mark main pattern 610 presenting the scarlet and the background pattern 620 presenting the silver white color may have a high contrast color difference to highlight the shape of the main pattern, so as to improve the alignment accuracy.

FIG. 6B is a cross-sectional view of an alignment mark structure using the copper layer as the mark main pattern according to an embodiment of the invention.

First, a first dielectric layer 602 is formed on the substrate, and the first dielectric layer 602 includes the mark main pattern 610. The mark main pattern 610 may be formed by the whole sheet of copper layer or the copper layer arranged in a square array to serve as the main pattern of the alignment mark. A method of forming the mark main pattern 610 formed by the whole sheet of copper layer or the copper layer arranged in a square array can be collaborated with the copper process in semiconductor fabrication. In an embodiment, a groove area is dug in the first dielectric layer 602, and a copper metal seed is implanted therein to form the mark main pattern 610 of the whole sheet of copper layer or the copper layer arranged in a square array.

Then, a second dielectric layer 604 is formed on the first dielectric layer 602 to cover or wrap the mark main pattern 610. Then, the background pattern 620 of the alignment mark structure is formed on the second dielectric layer 604. The background pattern 620 has an opening 622 located above the mark main pattern 610 and corresponding to the shape of the mark main pattern 610. That is, the opening 622 exposes the shape of the mark main pattern 610, or in one embodiment, the shape of the mark main pattern 610 may be defined by the opening 622 if the mark main pattern 610 is formed as a whole sheet of copper layer.

Then, a passivation layer is formed on the background pattern 620 to warp and protect the background pattern 620. For example, in an embodiment, a third dielectric layer 606 is formed on the second dielectric layer 604, where the third dielectric layer 606 can be an SRO layer. The third dielectric layer 606 is covered by a silicon nitride (Si₃N₄) layer 608. The third dielectric layer 606 and the silicon nitride (Si₃N₄) layer 608 can serve as the passivation layer of the alignment mark.

In the present embodiment, the mark main pattern 610 of the alignment mark structure 600 applies the whole sheet of copper layer or the copper layer arranged in a square array. In an embodiment, the mark main pattern 610 may be presented by smaller areas of copper of a same layer or different layers that are arranged in rectangles, so as to collaborate with the existing copper process. The material of the background pattern 620 is aluminium copper (AlCu) alloy. As described above, the aluminium copper (AlCu) alloy presents a color of silver white, and the whole sheet of copper layer or the copper layer arranged in a square array that serves as the mark main pattern presents a color of scarlet, so that a high contrast color difference is presented to highlight a shape of the main pattern, so as to improve the alignment accuracy. For example, an incident light has a reflection effect at the mark main pattern 610, as that shown by a referential number 601. Though the reflection effect is inferior to a reflection effect of the background pattern 620, as that shown by a referential number 603.

In the present embodiment, the shape of the mark main pattern 610 may be different according to different design requirements, and in an embodiment, it may be a cross shape for defining coordinate axes including the X-axis and the Y-axis, and regions thereon that extend upwards, downwards, leftwards and rightwards can increase contrast information, though the invention is not limited to the cross shape, and any shape that can be used as the alignment mark is applicable for the present embodiment.

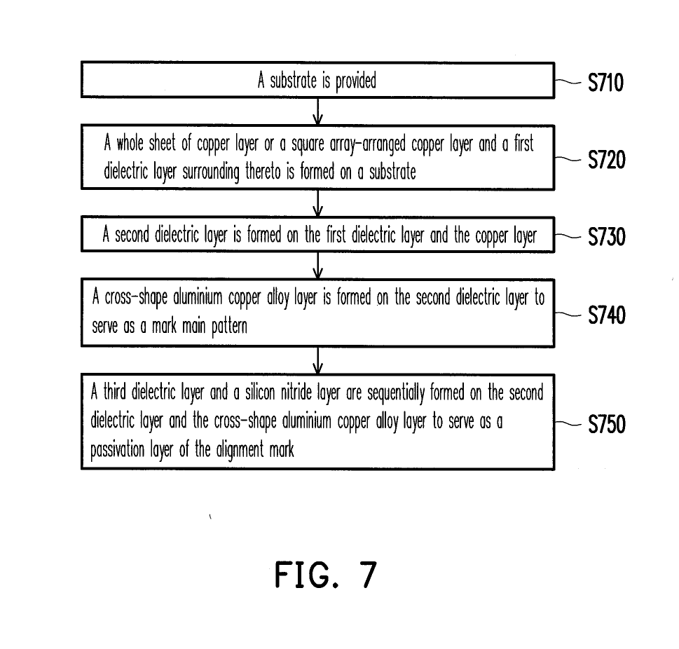

A fabrication process of using the whole sheet of copper layer or the copper layer arranged in a square array as the background pattern of the alignment mark structure is as that shown in FIG. 7. First, in step S710, a substrate is provided to from the alignment mark structure. In step S720, the whole sheet of copper layer or the copper layer arranged in a square array and a first dielectric layer surrounding thereto is formed on the substrate. In an embodiment, to achieve surface homogeneity, a fixed reflectivity is maintained, and a grinding process is performed to the first dielectric layer surrounding the whole sheet of copper layer to flatten the surface, so as to facilitate forming the alignment mark structure.

In step S730, a second dielectric layer is formed on the first dielectric layer and the copper layer, and the second dielectric layer covers a background layer. Then, in step S740, a cross-shape aluminium copper alloy layer is formed on the second dielectric layer to serve as a mark main pattern. In the present embodiment, a shape of the mark main pattern is the cross shape, which is used for defining coordinate axes including an X-axis and a Y-axis, and regions thereon that extend upwards, downwards, leftwards and rightwards can increase contrast information, though the invention is not limited to the cross shape, and any shape that can be used as the alignment mark is applicable for the present embodiment, for example, a T shape, an I shape or other shapes.

In step S750, a third dielectric layer and a silicon nitride layer are sequentially formed on the second dielectric layer and the cross-shape aluminium copper alloy layer to serve as a passivation layer of the alignment mark. The third dielectric layer is, for example, an SRO layer.

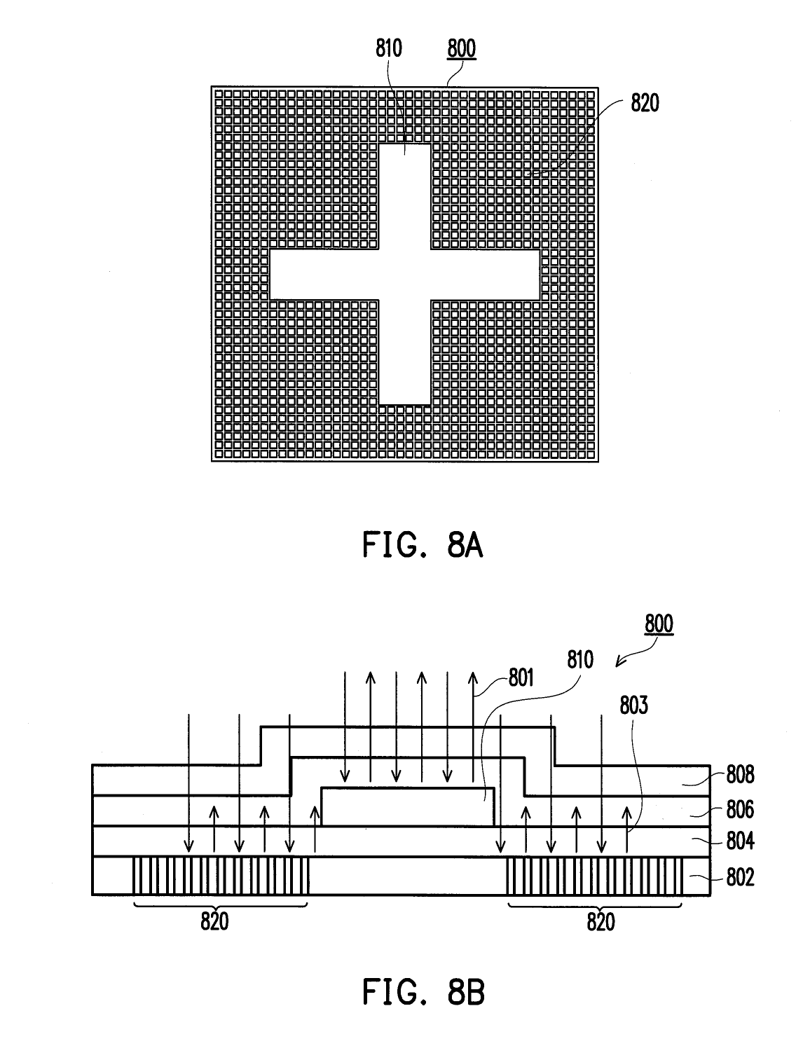

FIG. 8A is a top view of an alignment mark structure using the copper layer arranged in a square array as a background pattern and using an aluminium layer as a mark main pattern according to another embodiment of the invention. FIG. 8B is a light incident/reflection schematic diagram and a cross-sectional view of an alignment mark structure using the copper layer arranged in a square array as a background pattern and using an aluminium layer as a mark main pattern according to an embodiment of the invention.

FIG. 8A is a top view of an alignment mark structure using the copper layer as a background pattern of the alignment mark according to an embodiment of the invention. The alignment mark structure 800 of the embodiment includes a mark main pattern 810 and a background pattern 820. In an embodiment, the mark main pattern 810 may have different shapes according to different design requirements to facilitate the alignment procedure, for example, a cross shape, though the invention is not limited thereto. A material of the mark main pattern 810 is the aluminium copper (AlCu) alloy, which generally presents the silver white color. The background pattern 820 is the copper layer arranged in a square array. The copper layer arranged in a square array presents a color of scarlet to serve as the background of the present embodiment. According to the above descriptions, it is known that the mark main pattern 810 presenting the silver white color and the background pattern 820 presenting the scarlet may have a high contrast color difference to highlight the shape of the main pattern, so as to improve the alignment accuracy.

FIG. 8B is a cross-sectional view of the alignment mark structure using the copper layer arranged in a square array as the background of the alignment mark according to an embodiment of the invention. The substrate includes a first dielectric layer 802, and the first dielectric layer 802 includes the background pattern 820. The background pattern 820 can be formed by the copper layer arranged in a square array to serve as the background of the alignment mark. A pitch between each copper layer arranged in a square array can be determined according to a design requirement. A method of forming the background pattern 820 formed by the copper layer arranged in a square array can be collaborated with a copper process in semiconductor fabrication. In an embodiment, a groove area is dug in the first dielectric layer 802, and a copper metal seed is implanted therein to form the background pattern 820 of the copper layer arranged in a square array.

Then, a second dielectric layer 804 is formed on the first dielectric layer 802 to cover or wrap the background pattern 820. Then, the mark main pattern 810 of the alignment mark structure is formed on the second dielectric layer 804, and a passivation layer is formed on the mark main pattern 810 to warp and protect the mark main pattern 810. For example, in an embodiment, a third dielectric layer 806 is formed on the second dielectric layer 804, where the third dielectric layer 806 can be an SRO layer. The third dielectric layer 806 is covered by a silicon nitride (Si₃N₄) layer 808. The third dielectric layer 806 and the silicon nitride (Si₃N₄) layer 808 can serve as the passivation layer of the alignment mark.

In the present embodiment, the background pattern 820 of the alignment mark structure 800 applies the copper layer arranged in a square array. In an embodiment, the background pattern 820 can be presented by smaller areas of copper of a same layer or different layers that are arranged in rectangles, so as to collaborate with the existing copper process. The material of the mark main pattern 810 is aluminium copper (AlCu) alloy. As described above, the aluminium copper (AlCu) alloy presents the color of silver white, and the whole sheet of copper layer or the copper layer arranged in a square array that serves as the background presents a color of scarlet, so that a high contrast color difference is presented to highlight a shape of the main pattern, so as to improve the alignment accuracy. For example, an incident light has a sufficient reflection effect at the mark main pattern 810, as that shown by a referential number 801, though if the incident light falls on the background pattern 820, a reflection effect thereof is inferior to the reflection effect of the mark main pattern 810, as that shown by a referential number 803.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. An alignment mark, adapted to a copper process in fabrication of an integrated circuit (IC), and used for determining alignment of attaching the IC to a liquid crystal panel, the alignment mark comprising:
a background pattern, located in a first dielectric layer, wherein the background pattern is formed by a copper layer, and a surface of the background pattern covers a second dielectric layer; and
a mark main pattern, disposed upon the second dielectric layer, and located above a coverage area of the background pattern, wherein the mark main pattern is made of aluminium or aluminium copper alloy.

2. The alignment mark as claimed in claim 1, further comprising a passivation layer, comprising:
a third dielectric layer, covering the mark main pattern; and
a fourth dielectric layer, covering the third dielectric layer.

3. The alignment mark as claimed in claim 2, wherein the third dielectric layer is a stress relief oxide (SRO) layer and the fourth dielectric layer comprises a silicon nitride layer.

4. The alignment mark as claimed in claim 1, wherein a groove area is dug in the first dielectric layer to implant a copper metal seed, and electroplating and chemical mechanical polishing processes are performed to form the background pattern.

5. The alignment mark as claimed in claim 1, wherein the mark main pattern has a cross shape, an I-shape or a T-shape.

6. The alignment mark as claimed in claim 1, wherein the copper layer is a whole sheet of copper layer or arranged in a square array formed by rectangles.

7. An alignment mark, adapted to a copper process in fabrication of an integrated circuit (IC), and used for determining alignment of attaching the IC to a liquid crystal panel, and the alignment mark comprising:
a mark main pattern, formed by a copper layer and located in a first dielectric layer, wherein a second dielectric layer covers a surface of the mark main pattern; and
a background pattern, disposed upon the second dielectric layer, and located above the mark main pattern, wherein the background pattern is made of aluminium or aluminium copper alloy.

8. The alignment mark as claimed in claim 7, further comprising a passivation layer, comprising:
a third dielectric layer, covering the background pattern and the second dielectric layer; and
a fourth dielectric layer, covering the third dielectric layer.

9. The alignment mark as claimed in claim 8, wherein the third dielectric layer is a stress relief oxide (SRO) layer and the fourth dielectric layer comprises a silicon nitride layer.

10. The alignment mark as claimed in claim 7, wherein the background pattern has an opening located above a coverage area of the mark main pattern.

11. The alignment mark as claimed in claim 7, wherein the mark main pattern has a cross shape, an I-shape or a T-shape.

12. The alignment mark as claimed in claim 7, wherein the copper layer arranged in a square array formed by rectangles has one layer or different layers.

13. The alignment mark as claimed in claim 7, wherein the copper layer is arranged in a square array formed by rectangles, and a pitch of the copper layers arranged in a square array is adjusted according to color contrast between the background pattern and the mark main pattern.

14. The alignment mark as claimed in claim 7, wherein a groove area is dug in the first dielectric layer, and a copper metal seed is implanted to form the mark main pattern.

15. A method for fabricating an alignment mark, adapted to a copper process in integrated circuit (IC) fabrication, and comprising:
providing a substrate to form an alignment mark structure;
forming a copper layer and a first dielectric layer surrounding the copper layer on the substrate, wherein the copper layer form a background pattern;
forming a second dielectric layer on the first dielectric layer and the copper layer; and
configuring a mark main pattern on the second dielectric layer to locate above a coverage area of the background pattern, wherein the mark main pattern is made of aluminium or aluminium copper alloy, and forms contrast with a color of the background pattern to facilitate determining alignment for attaching an integrated circuit (IC) to a liquid crystal panel.

16. The method for fabricating the alignment mark as claimed in claim 15, further comprising:
forming a third dielectric layer to cover the mark main pattern; and
forming a fourth dielectric layer is formed to cover the third dielectric layer, wherein the third dielectric layer and the fourth dielectric layer serve as a passivation layer of the mark main pattern.

17. The method for fabricating the alignment mark as claimed in claim 16, wherein the third dielectric layer is a stress relief oxide (SRO) layer and the fourth dielectric layer comprises a silicon nitride layer.

18. The method for fabricating the alignment mark as claimed in claim 15, wherein a groove area is dug in the first dielectric layer to implant a copper metal seed, and electroplating and chemical mechanical polishing processes are performed to form the copper layer.

19. The method for fabricating the alignment mark as claimed in claim 15, wherein the mark main pattern has a cross shape, an I-shape or a T-shape.

20. The method for fabricating the alignment mark as claimed in claim 15, wherein the copper layer arranged in a square array formed by rectangles has one layer or different layers.

21. The method for fabricating the alignment mark as claimed in claim 20, wherein a pitch of the copper layers arranged in a square array is adjusted according to color contrast between the background pattern and the mark main pattern.

22. A method for fabricating an alignment mark, adapted to a copper process in integrated circuit (IC) fabrication, and comprising:
providing a substrate to form an alignment mark structure;
forming a copper layer and a first dielectric layer surrounding the copper layer on the substrate, wherein the copper layer form a mark main pattern;
forming a second dielectric layer on the first dielectric layer and the mark main pattern; and
configuring a background pattern on the second dielectric layer to locate above the mark main pattern, wherein the background pattern is made of aluminium or aluminium copper alloy, and forms contrast with a color of the mark main pattern to facilitate determining alignment for attaching an integrated circuit (IC) to a liquid crystal panel.
